(19) United States
(12) Patent Application Publication
(10) Pub. No.: US 2010/0178718 A1
(43) Pub. Date: Jul. 15, 2010

(54) METHODS FOR IMPROVING PERFORMANCE VARIATION OF A SOLAR CELL MANUFACTURING PROCESS

(76) Inventors: Maxim Kelman, Mountain View, CA (US); Karel Vanheusden, Los Altos, CA (US)

Correspondence Address: Foley & Lardner LLP, Suite 500, 3000 K STREET NW, Washington, DC, 20007, US

(21) Appl. No.: 12/352,857

(22) Filed: Jan. 13, 2009

(51) Int. Cl. H01L 21/66

(52) U.S. Cl. 438/15; 257/E21.529

(57) ABSTRACT

A method for optimizing a solar cell manufacturing process is described. The method includes determining a reference finger spacing value and a reference bulk lifetime for the solar cell manufacturing process. The method also includes measuring an actual bulk lifetime of a wafer with an in-line measurement tool. The method further includes calculating an optimal finger spacing value with a computer coupled to the in-line measurement tool, the optimal finger spacing value being the product of the reference finger spacing value and a square root of the actual bulk lifetime divided by the square root of the reference bulk lifetime. The method further includes forming a junction on the wafer, and depositing a set of busbars and a set of fingers on the wafer with a metal deposition device, wherein a distance between a first finger and a second finger of the set of fingers is about the optimal finger spacing value.

### FIELD OF DISCLOSURE

This disclosure relates in general to semiconductors and in particular to methods for improving performance variation of a solar cell manufacturing process.

### BACKGROUND

A solar cell converts solar energy directly to DC electric energy. Generally configured as a photodiode, a solar cell permits light to penetrate into the vicinity of metal contacts such that a generated charge carrier (electrons or holes (a lack of electrons)) may be extracted as current. And like most other diodes, photodiodes are formed by combining p-type and n-type semiconductors to form a junction.

The term junction refers to the region where the two regions (n-type region and p-type region) of the semiconductor meet. Although both p-type and n-type semiconductors each tend to be very conductive, the junction between them is a nonconductor. In general, this non-conducting layer, called the depletion zone, tends to occur because the electrical charge carriers in doped n-type and p-type silicon attract and eliminate each other in a process called recombination. Substantially affecting solar cell performance, carrier lifetime (recombination lifetime) is defined as the average time it takes an excess minority carrier (non-dominant current carrier in a semiconductor region) to recombine and thus become unavailable to conduct an electrical current. Likewise, recombination length is the average distance that a charge carrier travels before it recombines. In general, although increasing dopant concentration improves conductivity, it also tends to increase recombination. Consequently, the shorter the recombination lifetime or recombination length, the closer the metal region must be to where the charge carrier was generated.

A solar cell is typically formed on a silicon wafer, a substantially pure and nearly defect-free substrate. In a typical silicon wafer manufacturing process, called the Czochralski (cz) method, a monocrystalline wafer is produced by slowly raising a seed from a crucible with a molten silicon bath (melt), doped with a first dopant (commonly boron) in order to form a single-crystal ingot or boule. This ingot is then cut into wafers upon which a second dopant (commonly phosphorous) is diffused forming the emitter region in order to complete the p-n junction. A passivation and antireflection coating is then added on the emitter region. Finally, metal contacts are added in order to extract generated charge.

However, impurity concentration in the melt and are not constant as the ingot is pulled. The distribution of impurities in the solid boule is generally dependent on the segregation coefficient of the impurity type, how quickly the ingot is pulled from the melt, and fluid motion/mixing in the crucible. For example, dopant concentration in the boule as a function of the solidified fraction may be shown as:

Cₛ=C₀k₀(1−f)^{k}^{₀}⁻¹ [EQUATION 1]

where,

Cₛ is the concentration of dopant in solid;

C₀ is the initial concentration of dopant in the melt;

k₀ is the segregation coefficient (C_{solid}/C_{liquid}) defined by phase diagram for each impurity; and

f is the fraction of solidified melt.

Consequently, the variation in dopant/impurity content as a function of position in the boule creates a set of wafers with continuously varying doping/impurity and resistivity level, and resulting carrier lifetime. However, once manufacturing parameters and recipes are established, is it difficult to reliably optimize these for variations in wafer characteristics, such as carrier lifetime. That is, although for a given wafer, a more optimal manufacturing process could theoretically be used that yields a better performing solar cell, altering the manufacturing process itself introduces greater process variability and thus may reduce overall process yields.

For example, patterns for screen printing or photolithography cannot be modified easily. Pattern modification would require new screens or masks which are difficult to replace and expensive to acquire. Thus, the solar cells are generally placed in suboptimal statistical performance bins, each bin including a set of solar cells within some standard deviation of a performance mean.

In view of the foregoing, there are desired methods of improving performance variation of a solar cell manufacturing process.

### SUMMARY

The invention relates, in one embodiment, to method of optimizing a solar cell manufacturing process. The method includes determining a reference finger spacing value and a reference bulk lifetime for the solar cell manufacturing process. The method also includes measuring an actual bulk lifetime of a wafer with an in-line measurement tool. The method further includes calculating an optimal finger spacing value with a computer coupled to the in-line measurement tool, the optimal finger spacing value being the product of the reference finger spacing value and a first square root of the actual bulk lifetime divided by a second square root of the reference bulk lifetime. The method further includes forming a junction on the wafer, and depositing a set of busbars and a set of fingers on the wafer with a metal deposition device, wherein a distance between a first finger and a second finger of the set of fingers is about the optimal finger spacing value.

The invention relates, in another embodiment, to a method for optimizing a solar cell manufacturing process. The method includes determining a reference finger spacing value and a reference bulk lifetime for the solar cell manufacturing process. The method also includes measuring an actual bulk lifetime of a wafer with an in-line measurement tool, the wafer including a rear surface. The method further includes calculating an optimal finger spacing value with a computer coupled to the in-line measurement tool, the optimal finger spacing value being the product of the reference finger spacing and a first square root of the actual bulk lifetime divided by a second square root of the reference bulk lifetime. The method also includes depositing a set of metal contacts on the rear wafer surface, the rear wafer surface having a set of p-type regions and a set of n-type regions, the set of metal contacts including a busbar and a set of fingers, wherein a first metal contact of the set of metal contacts is deposited on the set of p-type regions, and a second metal contact of the set of metal contacts is deposited on the set of n-type regions, wherein the first metal contact is interdigitated with the second metal contact, and a distance between two proximately located fingers of the first metal contact or two proximately located fingers of the second metal contact is about the optimal finger spacing value.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows a simplified diagram of a monocrystalline boule as made by the Czochralski (cz) method, in accordance with the invention;

FIG. 2A shows a simplified diagram of dopant concentration along the longitudinal length of a typical boule, in accordance with the invention;

FIG. 2B shows a simplified diagram of resistivity along the longitudinal length of a typical boule, in accordance with the invention

FIG. 3A shows a simplified diagram of minority carrier lifetime along the longitudinal length of a typical boule, in accordance with the invention.

FIG. 3B shows a simplified diagram comparing carrier lifetime to the solar cell short circuit current, in accordance with the invention;

FIGS. 4A-B shows a simplified set of diagrams shows describing a front-side point contact solar cell, in accordance with the invention;

FIG. 5 shows a simplified diagram of a back contact solar cell, in accordance with the invention;

FIG. 6A shows a simplified diagram of bulk lifetime for a given bulk wafer resistivity for the solar cells as shown in FIGS. 4A-B and 5, in accordance with the present invention;

FIG. 6B shows a simplified diagram of optimal finger spacing for a given bulk lifetime for the solar cells as shown in FIGS. 4A-B and 5, in accordance with the present invention;

FIG. 6C shows a simplified diagram of a set of solar cell efficiency probability density functions, in accordance with the invention;

FIGS. 7A-B show a set of simplified diagrams of a solar cell manufacturing process with optimized metallization, in accordance with the present invention; and

FIGS. 8A-C show a set of simplified diagrams of a solar cell manufacturing process with optimized metallization and silicon-metal interface region formation, in accordance with the present invention.

### DETAILED DESCRIPTION

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

As previously described, in standard solar cell manufacturing, it is difficult to individually optimize the performance characteristics of a solar cell to the specific characteristics of a given silicon substrate, such as dopant concentration or minority carrier lifetime. In an advantageous manner, the inventors believe that a solar cell manufacturing line may be configured, such that efficiency is optimized for each solar cell based on its measured lifetime. That is, efficiency may be optimized by flexibly adjusting the finger pitch of the metal contacts and a set (one or more) of silicon-metal interface regions using methods such as inkjet printing, light-induced plating, laser sintering of metal powder, and metal aerosol jetting using a pattern optimized specifically for the electrical properties of the particular wafer.

Unlike screen printing where the pattern is fixed, flexible metallization techniques allow for the fast modification of the metal pattern without any downtime or added cost. For example, an inkjet printer may be used to deposit a relatively thin layer of silver particles in a shallow pattern on the wafer surface, and then nickel may be added onto the pattern using electroless plating to form thick metal contacts.

Alternatively, the initial thin metallic layer may be thickened using light-induced plating. In this method a wafer is immersed in an electro-plating bath with and only contacted at the fully metallized rear. By illuminating the cells with light, the front electrodes are at a negative potential, high enough to stimulate deposition of Ag ions.

In addition, metal particles may be atomized and then jetted in an aerosol that is deposited on the silicon wafer surface. A laser may then be used to sinter the deposited metal particles on the surface of the cell to form the contact lines.

In the case of optimizing the set of silicon-metal interface regions, heavily doped Group IV nanoparticles may be deposited onto a lighter doped (i.e., higher resistivity with the same dopant type) wafer region, such that these doped nanoparticles are between a subsequent metal layer and the wafer region surface.

In general, a nanoparticle is a microscopic particle with at least one dimension less than 100 nm. The tern “Group IV nanoparticle” generally refers to hydrogen terminated Group IV nanoparticles having an average diameter between about 1 nm to 100 nm, and composed of silicon, germanium, carbon, or combinations thereof. The term “Group IV nanoparticle” also includes Group IV nanoparticles that are doped. In comparison to a bulk material (>100 nm) which tends to have constant physical properties regardless of its size (e.g., melting temperature, boiling temperature, density, conductivity, etc.).

Because of their small size, nanoparticles also tend to be difficult to manipulate. Consequently, in an advantageous manner, assembled nanoparticles may be suspended in a colloidal dispersion or colloid, such as an ink, in order to transport and store the nanoparticles.

In general, the Group IV nanoparticles are transferred into the colloidal dispersion under a vacuum, or an inert substantially oxygen-free environment. In addition, the use of particle dispersal methods and equipment such as sonication, high shear mixers, and high pressure/high shear homogenizers may be used to facilitate dispersion of the nanoparticles in a selected solvent or mixture of solvents.

This process is generally described in U.S. patent application Ser. No. 12/029,838, filed Feb. 12, 2008, and entitled Methods and Apparatus for Creating Junctions on a Substrate, the entirety of which is incorporated herein by reference.

Conventional solar cells are relatively simply to manufacture, having a front-side (solar-facing) contact (usually fingers connected to a set of busbars) and a back-side contact (usually an aluminum back surface field with silver contact pads). As the efficiency of a solar cell is directly related to the amount of sunlight received, a front-side contact must generally be optimized to minimize losses due to shading. Determined by the transparency of the top surface, shading losses are defined as the fraction of the top surface covered by metal. The transparency is determined by the width of the metal lines on the surface and on the spacing of the metal lines.

Front-side contacts are generally applied via a silk-screening process, a printing technique that makes use of a squeegee to mechanically force a metallic particle paste directly onto the wafer through a screen. The screen itself is generally mounted into an aluminum frame with a design comprising areas that are blocked off with a pre-defined stencil (positive of the front grid to be printed) and areas that are open where the paste will go through later on. Consequently, a given process design typically uses a fixed set of screens optimized for an overall process performance mean. In contrast, flexible printing techniques, such as inkjet printing, allow front-side contract patterns to be individually tailored to each solar wafer.

On the contrary, back contact solar cells do not suffer from shading losses since all the contacts are on the rear of the solar cell. However, since metal-silicon interfaces tend to have high charge carrier recombination rates, care must be taken when configuring the contacts on the rear surface. In the most common configurations, emitter regions and the BSF regions are generally applied in an interdigitated fashion via a series of silk-screening processes, as described above. As with conventional solar cells, flexible printing techniques, such as inkjet printing, allow back-contract patterns to be individually tailored to each solar wafer.

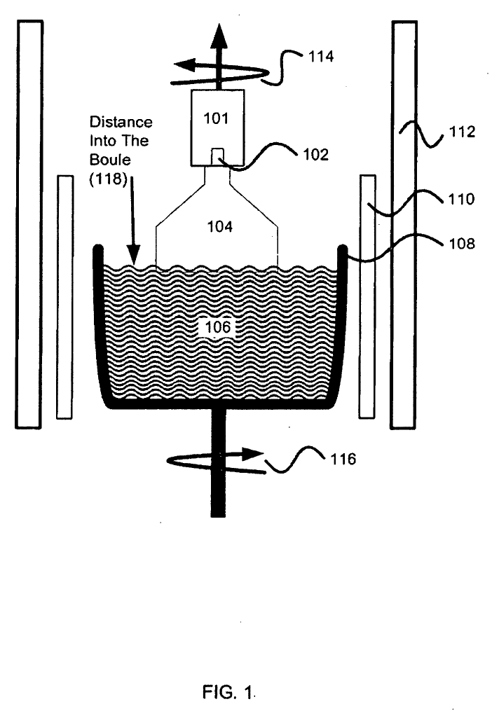

Referring now to FIG. 1, a simplified diagram is shown of a monocrystalline boule as made by the Czochralski (cz) method, in accordance with the invention. Typically, a silicon melt 106 (with appropriate dopants) is first formed in a quartz or graphite crucible with a fused silica lining 108 that is heated by graphite heaters 110 in a vacuum vessel 112 with argon ambient. The molten sand bath 106 is rotated in a first direction 116 while a silicon crystal seed 102 is inserted, rotated in a second counter direction 114, and then slowly extracted or pulled from quartz crucible 108 in order to form boule 104.

However, as previously described, as the forming boule 104 is slowly extracted from quartz crucible 108, dopants and impurities tend to segregate from the solid boule 104, and into the molten sand bath 106. That is, for any given radial cross-section of the boule, the concentration of dopants and impurities tends to increase as the distance from the seed (into the boule) 118 increases.

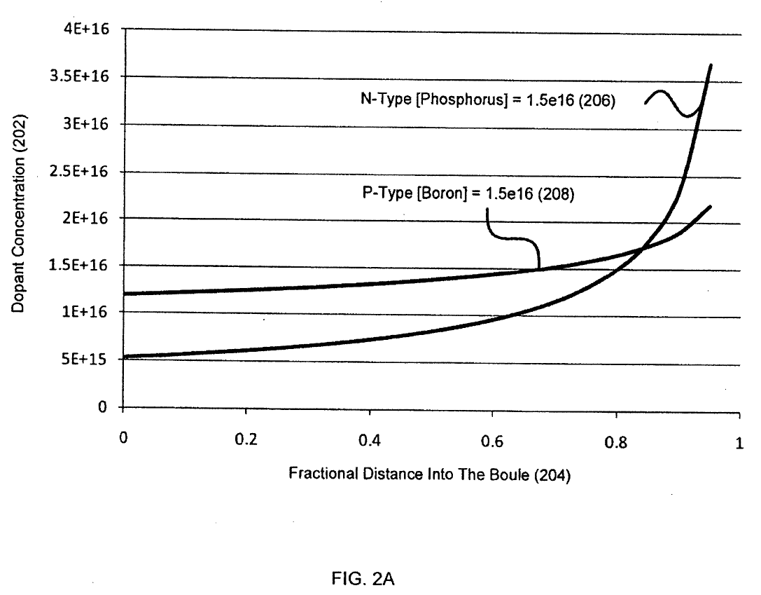

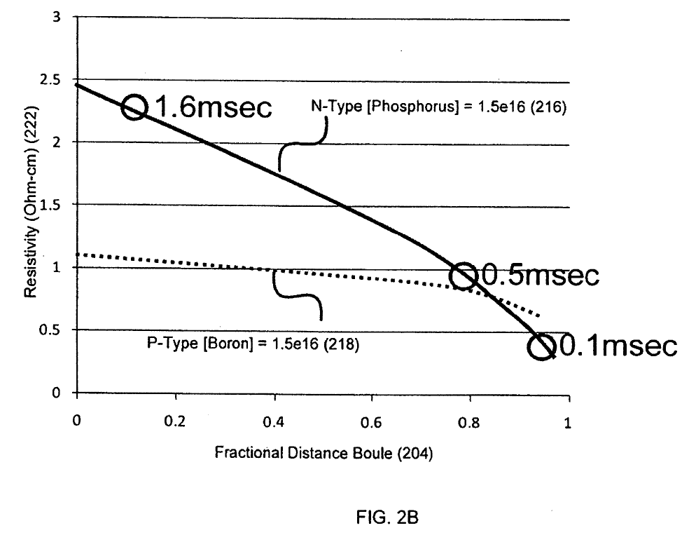

Referring now to FIG. 2A, a simplified diagram is shown of dopant concentration along the longitudinal length of a typical boule, in accordance with the invention. Dopant concentration 202 is shown along the vertical axis, while fractional distance into the boule 204 (increasing away from seed 102) is shown along the horizontal axis. A first n-type plot is shown for phosphorous 206 at melt concentration of about 1.5×10¹⁶(1.5E16), while a second p-type plot 208 is shown for boron at a melt concentration of about 1.5×10¹⁶(1.5E16).

All common impurities have different solubilities in the solid and in the melt. An equilibrium segregation coefficient kₒ can be defined to be the ratio of the equilibrium concentration of the impurity in the solid to that in the liquid at the interface, i.e. kₒ=Cₛ/Cₗ. Dopants and other impurities tend to segregate when the silicon boule is pulled from the molten sand bath, such that the impurity concentration in the melt and the solidifying boule are different. As a result, the impurity concentration in the melt and in the solid increases as the boule is pulled. The concentration of dopants/impurities in the solid boule is generally dependent on the distance into the boule, segregation coefficient of the impurity, how quickly the ingot is pulled from the melt, and fluid motion/mixing in the crucible.

In general, for both types of donor atoms (i.e., phosphorous, etc.) or acceptor atoms (i.e., boron, etc.), increasing the dopant density for a particular dopant type in a region tends to lead to a reduction in the resistance in that region. However, as previously described, increasing dopant density also increases the likelihood of charge carrier recombination

Referring now to FIG. 2B, a simplified diagram is shown of resistivity along the longitudinal length of a typical boule, in accordance with the invention. Resistivity (Ohm-cm) 222 is shown along the vertical axis, while fractional distance into the boule 204 is shown along the horizontal axis. A first n-type plot is shown for phosphorous 216 at melt concentration of about 1.5×10¹⁶(1.5E16), while a second p-type plot 218 is shown for boron at a melt concentration of about 1.5×10¹⁶(1.5E16).

For an n-type boule, doped nominally at 1.5×10¹⁶(1.5e16) phosphorous atom concentration, the resistivity is about 2.25 Ohm-cm and the minority carrier lifetime is about 1.6 msec at a fractional distance of about 0.1 (10%) into the boule. As the fractional distance is increased to about 0.75 (75%) into the boule, the resistivity decreases to about 0.8 Ohm-cm (corresponding to a higher dopant concentration) and the minority carrier lifetime decreased to about 0.5 msec. As the a fractional distance further increases to about 0.95 (95%) into the boule, the resistivity decreases to about 0.4 Ohm-cm and the minority carrier lifetime also decreases to about 0.1 msec.

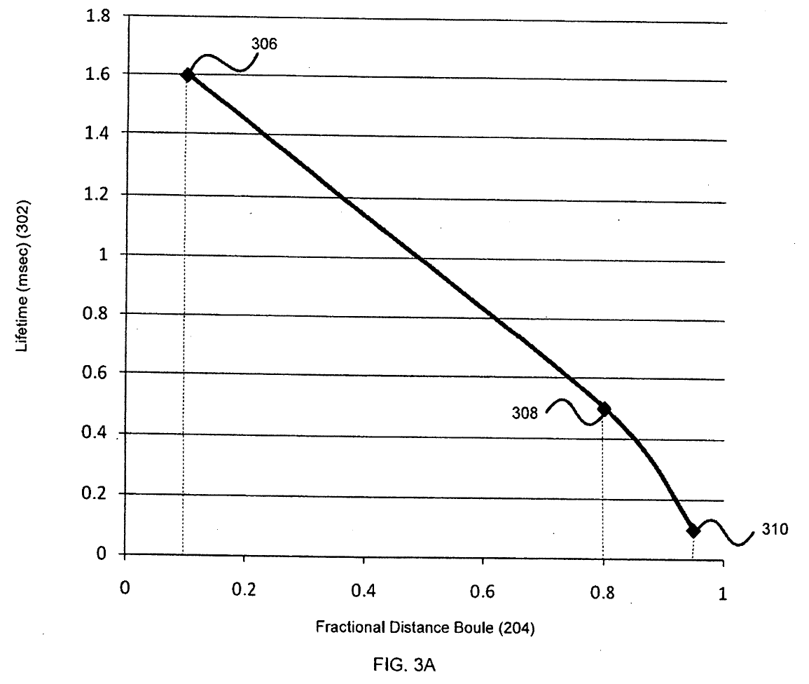

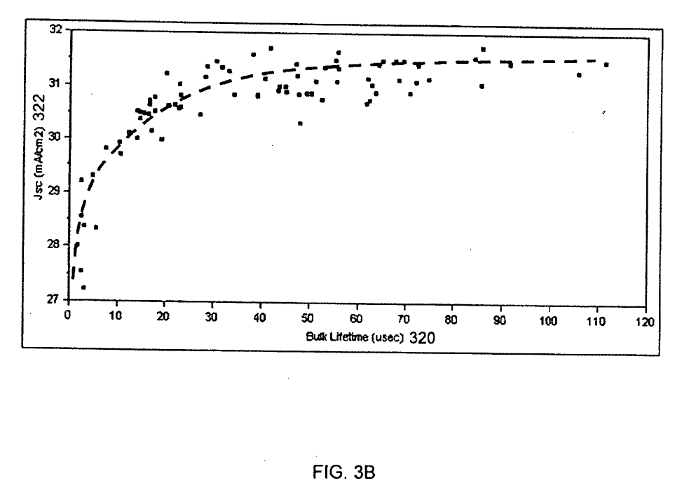

Referring now to FIG. 3A, a simplified diagram is shown of lifetime along the longitudinal length of a typical boule, in accordance with the invention. Lifetime (msec) 302 is shown along the vertical axis, while fractional distance into the boule 204 is shown along the horizontal axis. As previously stated, dopant concentration level will tend to increase much faster further into the boule, decreasing both resistivity and lifetime. Here, at a fractional distance of about 0.1 (10%) 306 into the boule, the lifetime is about 1.6 msec. At a fractional distance of about 0.8 (80%) 308 into the boule, the lifetime decreased to about 0.5 msec. At a fractional distance of about 0.95 (95%) 310 into the boule, the lifetime decreases still further to about 0.1. msec.

Referring now to FIG. 3B, a simplified diagram is shown comparing carrier lifetime to measured current, in accordance with the invention. Lifetime (μsec) 320 is shown along the horizontal axis, while J_{sc} (mA/cm²) 322 is shown along the vertical axis. As can be seen, below a bulk lifetime of about 30 μsec, generated current begins to substantially decrease, as a greater percentage of the front surface of the solar cell covered must be covered by metal in order to accommodate the reduced charge carrier recombination length.

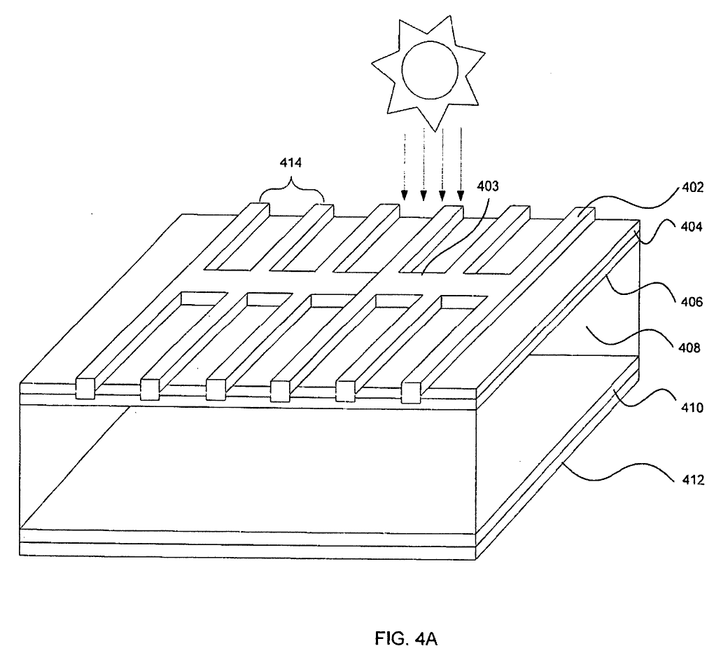

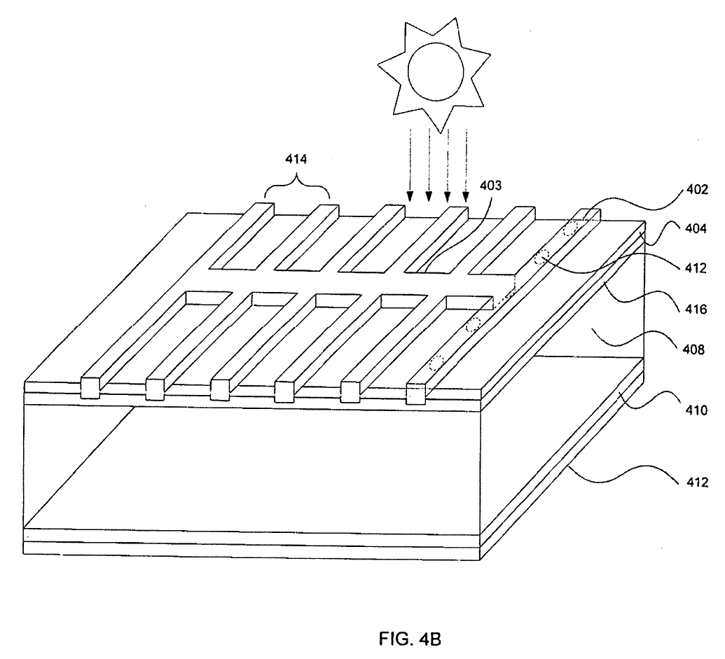

Referring now to FIGS. 4A-B, a simplified set of diagrams is shown of a conventional front-contact solar cell, in accordance with the invention.

FIG. 4A shows a simplified diagram of a conventional front-contact solar cell without optimized silicon-metal interface regions, in accordance with the invention. In general, an emitter 406 (here phosphorous doped) is diffused into counter-doped wafer 408 (here boron doped) in order to create the p-n junction required for charge separation and extraction.

Above and in electrical contact with the emitter 406 (typically through a channel or cavity in a dielectric or directly on top of an anti-reflective coating 404) is a front metal contact, comprising a set of fingers 402 (here with a width of about 100 um silver) and a set of busbars 403. Typically made out of printed silver paste, the front metal contact is optimized to extract the charge carriers (here electrons) created in the wafer when light is absorbed. The front metal contact is also typically configured with a reduced horizontal surface area (thus minimizing losses due to shading, which tend to reduce the generated current), and an increased cross-sectional volume (thus reducing the series resistance of the device, which tends to increase the efficiency of the device).

Deposited between front metal contact and wafer 408 is anti-reflective coating 404 (here a silicon nitride anti-reflection layer with a thickness of about 75 nm, n=2.05, Q_{f}=2e12, and S=1000). In general, untreated silicon substrates often reflect more than 30% of incident light. Consequently, in order to reduce this reflected energy and thus directly improve efficiency, the silicon substrate is generally textured and optimized with anti-reflective coatings, such as silicon nitride (SiNx). In addition, anti-reflective coating 404 helps passivate the surface of emitter 406, minimizing both contamination of the wafer bulk from external sources, as well as substantially reduce minority carrier recombination caused by dangling Si bonds or imperfections in the counter-doped wafer 408 surface.

On the back-side of wafer 408 is often a heavily doped region (of the same type as the wafer) which creates a BSF (back surface field) 410. Minimizing the impact of rear surface recombination, a properly configured BSF tends to repel those oppositely charged carriers that are located closer to the back-side. That is, the interface between BSF 410 and wafer 408 tends to introduce a barrier to minority carrier flow to the rear surface, resulting in higher levels of minority carrier concentrations in the wafer absorber. For example, Al (aluminum) or B (boron) may be added to a p-type wafer to repel electrons. In contrast, for an n-type wafer, P (phosphorous) may be added to repel holes. In addition, silver (Ag) pads are generally inserted in order to facilitate soldering for interconnection into modules.

Pitch 414 refers to the center-to-center distance between two proximately positioned fingers. In an advantageous manner, optimal finger spacing may be calculated for the specific wafer bulk lifetime, such that recombination is minimized and efficiency optimized.

FIG. 4B shows the simplified diagram of a FIG. 4A, with the addition of a set of silicon-metal interface regions, in accordance with the invention. In general, for an emitter region of a given dopant concentration level, a lower dopant concentration tends to reduce charge carrier recombination relative to higher dopant concentrations, but also tends to increase silicon-metal interface resistivity, which is detrimental to solar cell efficiency. Here a set of higher doped silicon-metal interface regions 412 have been deposited between the front metal contact and a lower doped (same dopant type) emitter 416.

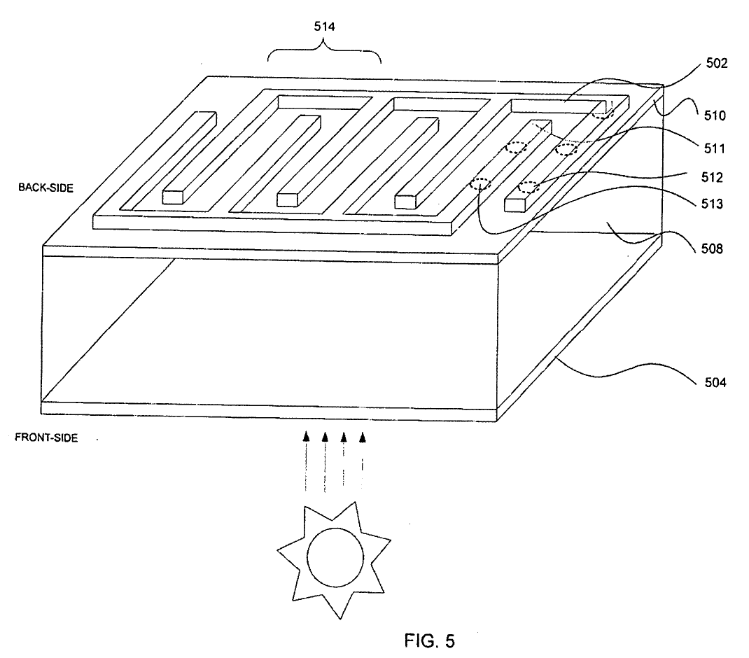

Referring now to FIG. 5, a simplified diagram of a back contact solar cell is shown, in accordance with the invention. Unlike front-contact solar cells as shown in FIGS. 4A-B, back-contact solar cells generally have both the emitter and the BSF, and thus the corresponding metal contacts, on the rear of the solar in an interdigitated configuration. Consequently, front-side shading losses are substantially eliminated which tends to improve overall solar cell efficiency. However, as with front-side solar cells, charge carrier recombination on the rear surface must be balanced against silicon-metal interface resistivity in order to optimize efficiency as previously described. Consequently, the pitch 514 between two proximately positioned fingers must be also be optimized for a given wafer resistivity and minority carrier lifetime in order to maximize charge carrier collection.

In a common configuration, a set of p-type (emitter) regions 512 and a set of n-type (BSF) regions 513 are diffused into or onto an n-type (phosphorous doped) silicon wafer 508. In order to extract the charge carriers, an emitter metal contact 502 is deposited on the set of p-type regions 512, and a BSF metal contact 511 is deposited on the set of n-type regions.

In addition, a front-side layer 504 comprising a FSF (front-surface field) and an anti-reflective coating (as previously described) is also deposited. The FSF is similar in function to a BSF in that it tends to repel minority carriers (here electrons) from the front of the solar cell.

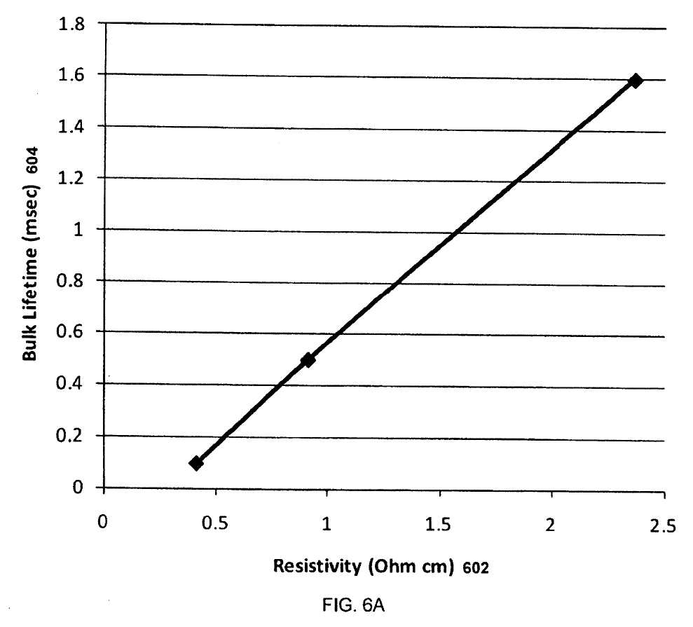

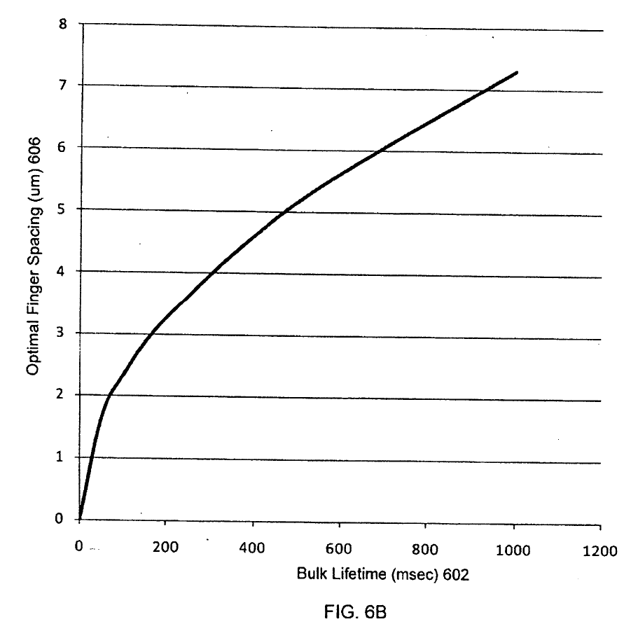

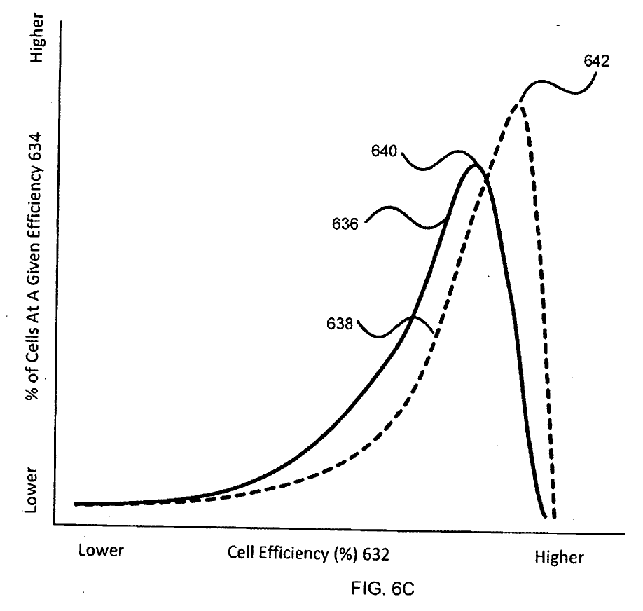

Referring now to FIG. 6A, a simplified diagram of bulk lifetime for a given resistivity measurement of a solar cell shown in FIGS. 4A-B and 5. Resistivity (Ohm-sq) 602 is shown along the horizontal axis, while bulk lifetime τ (msec) 604 is shown along the vertical axis. As previously described, as bulk resistivity is inversely related to dopant concentration and directly related to bulk lifetime. That is, as dopant concentration decreases, resistivity increases as does the bulk lifetime of charge carriers.

FIG. 6B shows a simplified diagram of optimal finger spacing for a given bulk lifetime of a solar cell shown in FIGS. 4A-B and 5. Optimal finger spacing l (μm) 606 is shown along the vertical axis, while bulk lifetime τ (msec) 602 is shown along the horizontal axis. As previously described, as bulk lifetime increase, the optimal finger spacing also increases, minimizing shading losses and increasing efficiency. Consequently, the relationship between the bulk lifetime of wafer without a p-n junction, and the theoretical optimal finger spacing for the substantially completed solar cell (e.g., p-n junction, metallization, and passivation) may be shown as:

lα\sqrt{Dτ} [EQUATION 2]

where D is the minority carrier diffusion coefficient in units of (cm²/sec).

However, in addition to variations caused by bulk lifetime τ, the variability of a solar cell manufacturing process also tends to be related to several factors, such as incoming wafer quality, texture quality, junction depth (sheet rho), anti-reflective coating thickness and refractive indices, metallization parameters (area, thickness, width, back-contact properties), cell parameters, etc.

In an advantageous manner, the inventors believe that factors other than lifetime τ may be substantially removed from the calculation of optimal finger spacing by first selecting and then comparing the bulk lifetime to the efficiency of a set of representative solar cells that have been processed through the manufacturing line. The reference finger spacing (l_{reference}) and reference lifetime (τ_{reference}) that results in the greatest measured efficiency are then selected and used to calculate an optimal finger spacing lₒₚₜᵢₘₐₗ based on an measured bulk lifetime τ_{actual} for a specific cell:

$${l}_{optimal} = {l}_{reference} \sqrt{\frac{{τ}_{actual}}{{τ}_{reference}}} \qquad [ EQUATION 3 ]$$

Consequently, during the manufacturing process, the bulk lifetime of a wafer may be measured with an in-line measurement tool such as a flash tester, a four-point probe, and/or a photoluminescence imaging tool.

Flash test measurement generally involves exposing the wafer to a light source, which increases the rate of generation of excess carriers (i.e. the difference between the actual carrier concentration and the equilibrium carrier concentration). Recombining when the light source is removed, the excess carriers return to an equilibrium level at a rate that is dependent of their concentration. The time constant of this exponential decay is the carrier recombination lifetime of the semiconductor.

Four-point probe measurement generally involves measuring spreading resistance with four electrical contacts. An excitation current is applied between the outer two contacts, and the voltage drop measured between the inner two. From their ratio, a resistance is computed. The sheet resistively in ohms per square of the sample may then be computed using this resistance along with a correction factor, which in turn, may be correlated with bulk lifetime.

Photoluminescence imaging generally involves illuminating a wafer with an external light source and observing the resulting emission of light. The integrated intensity of the emitted light may then be correlated with bulk carrier lifetime (τ_{actual}).

A computer, coupled to the inline measurement tool, may then be used to electronically calculate an optimal finger spacing (lₒₚₜᵢₘₐₗ) from bulk carrier lifetime. In a common configuration, the computer includes one or more processor readable storage devices having processor readable code embodied on the processor readable storage devices, the processor readable code for programming one or more processors configured to calculate an optimal finger spacing (lₒₚₜᵢₘₐₗ) and then transmit the resulting calculation over a network to a set of tools configured to deposit the metal contacts (fingers and busbar(s)) and/or layer (region) contact (interface) layers.

Referring now to FIG. 6C, a simplified diagram is shown of a set of solar cell efficiency probability density functions, in accordance with the invention. In general, for any manufacturing process, there tends to be natural or common causes of variation, such as specifications of raw materials, differences is tools, etc. These variations tend to be small, and are generally near to the average value. The pattern of variation tends form a distribution curve. In the case of solar cell manufacturing, the efficiency distribution across relatively high volume manufacturing process tends to be a log-normal distribution, with the mean value being substantially closer to the maximum efficiency value than to the minimum efficiency value. Here, efficiency may be modeled as log-normal if it can be thought of as the multiplicative product of many independent factors (e.g., tool variance, contamination, etc.) which are positive and close to 1.

Consequently, if cell efficiency 632 (T) (as shown on the horizontal axis) is modeled as a random variable with a normal distribution, then the % of cells at a given efficiency 634 (f(T)) may have a log-logistic distribution that may be shown as:

$$f ( T ) = \frac{{e}^{2}}{σ {T ( 1 + {e}^{2} )}^{2}} \qquad [ EQUATION 4 ]$$

where,

$$z = \frac{{T}^{′} - μ}{σ}$$

T′=ln(T)

μ=scale parameter

s=shape parameter

0<t<∞, −∞<μ<∞, and 0<σ<1.

Here, curve 636 shows a possible distribution for solar cells manufactured without flexible front-side techniques as previously described, while curve 638 shows a possible distribution for solar cells manufactured with flexible front-side that optimize for variation in carrier lifetime. The difference between lower peak 640 and higher peak 642 represents the increase in the percentage of cells at higher efficiency that may be achieved.

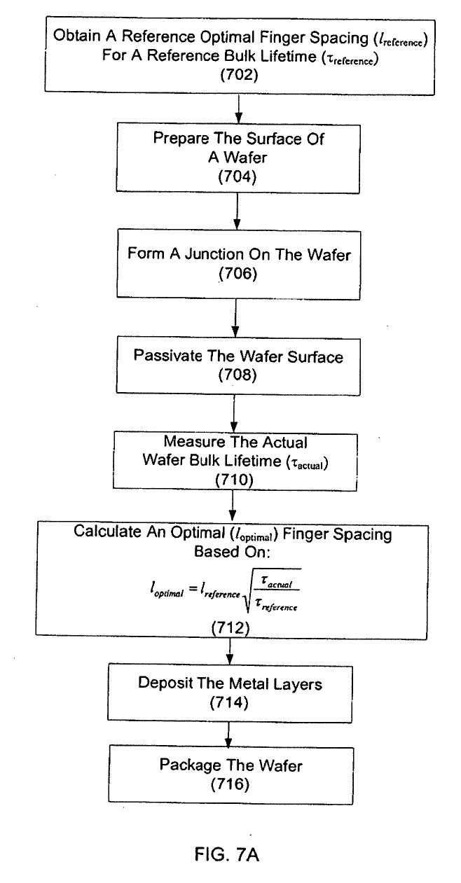

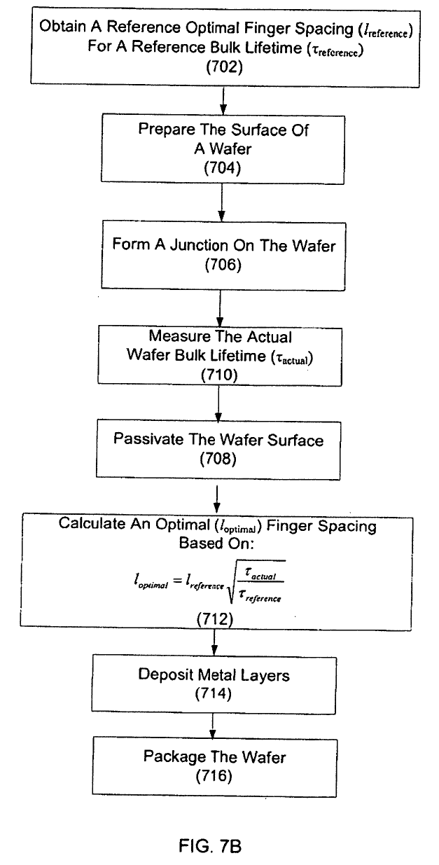

Referring now to FIGS. 7A-B, a set of simplified diagrams is shown of a (front-contact or back-contact) solar cell solar cell manufacturing process with optimized metallization, in accordance with the present invention. FIG. 7A shows the solar cell manufacturing process in which the bulk wafer lifetime is measured after wafer passivation.

Initially at 702, for a given manufacturing process, a reference optimal finger spacing is obtained for a reference bulk lifetime. A set of wafers with substantially the same bulk lifetime is selected and processed through the manufacturing line, wherein each processed wafer has a different finger spacing. The resulting efficiencies are then measured and the finger spacing (reference finger spacing) the results with the greatest efficiency (reference efficiency) is selected or derived.

Next at 704, the surface of the wafer is prepared using techniques such as exposure to alkaline and/or acid solutions, as well as plasma etching, in order to remove damage caused by the wire saw used to cut silicon ingots into wafers. In general, saw damage has to be removed from the silicon wafer surface, in order to increase the mechanical strength of the silicon wafer as well as decrease recombination in the surface region caused by impurities in a crystalline lattice. This step can also be used to minimize the reflectivity of the wafer surface which improves the light capture efficiency of the solar cell.

Next at step 706, the junction is formed on the silicon wafer typically by a tube diffusion process. In general, the silicon wafers are placed into a quartz tube and is heated up to around 800 to 900° C. Nitrogen flows as a carrier gas through a bubbler, connected to the quartz tube, filled with liquid phosphorus oxychloride POCl₃, wherein phosphorus diffuses into the silicon forming a p-n junction with the p-type base.

Next at step 708, the surface is passivated. Typically, a layer of silicon nitride with hydrogen is deposited onto the front side of the solar cell as an antireflection coating that also serves to passivate the silicon wafer and reduce recombination losses.

Next, at step 710, the bulk lifetime for the wafer is measured using an in-line measurement method such as a flash tester, a 4-point probe, or a photoluminescent imaging device.

At 712, an optimal finger spacing is calculated by a computer a based on:

$${l}_{optimal} = {l}_{reference} \sqrt{\frac{{τ}_{actual}}{{τ}_{reference}}} \qquad [ EQUATION 5 ]$$

where τ_{reference} is the reference bulk lifetime, τ_{actual} is the bulk lifetime of the current wafer, l_{reference} is the reference optimal finger spacing, and lₒₚₜᵢₘₐₗ is the optimal finger spacing of the current wafer.

At step 714, the metal layers are then deposited in a pattern with a metal deposition tool using methods such as inkjet printing, light-induced plating, laser sintering of metal powder, and metal aerosol jetting. In general, the metal deposition tool may use a set of pre-calculated spatial patterns, wherein each optimal finger spacing would be associated with at least one pattern. In contrast, the spatial pattern may be calculated on the fly for each optimal finger spacing. For example, for metal layers deposited with an ink printer, a deposition pattern generally must be defined in a page description language that defines the image to be printed. In addition, rear metal contacts are also deposited, commonly with a screen process.

Finally, at step 716, the solar cell is packaged. In general, sets of solar cells are electrically interconnected by a layer of the encapsulant material ethylene vinyl acetate (EVA) on the front and the back. The laminated cells are then covered with two pieces of glass.

FIG. 7B shows the solar cell manufacturing process in which the bulk wafer lifetime is measured before wafer passivation. That is, after forming the junction on the silicon wafer at step 706, the bulk lifetime for the wafer is measured at step 710, and then the wafer surface is passivated at step 708.

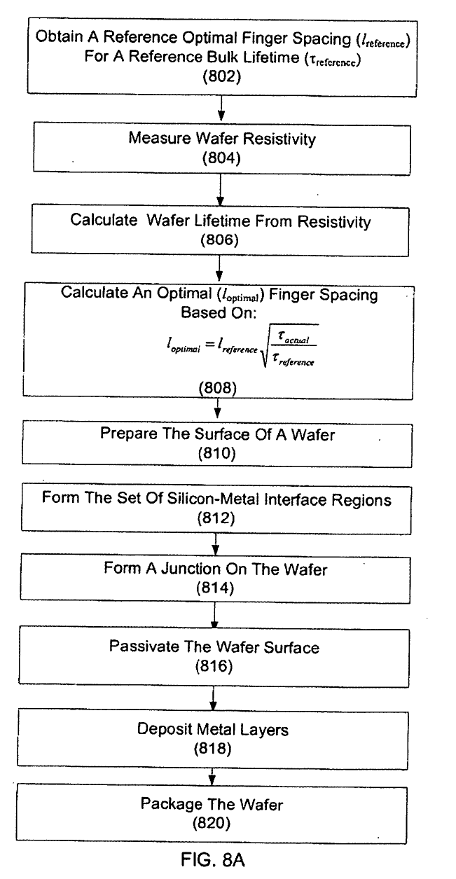

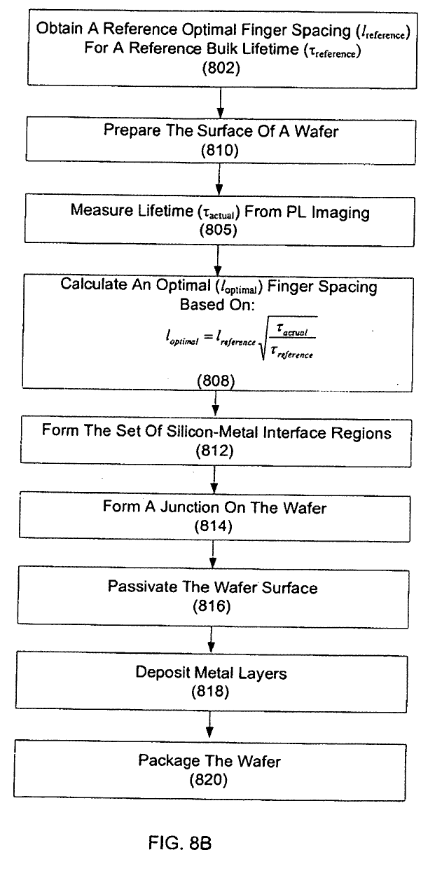

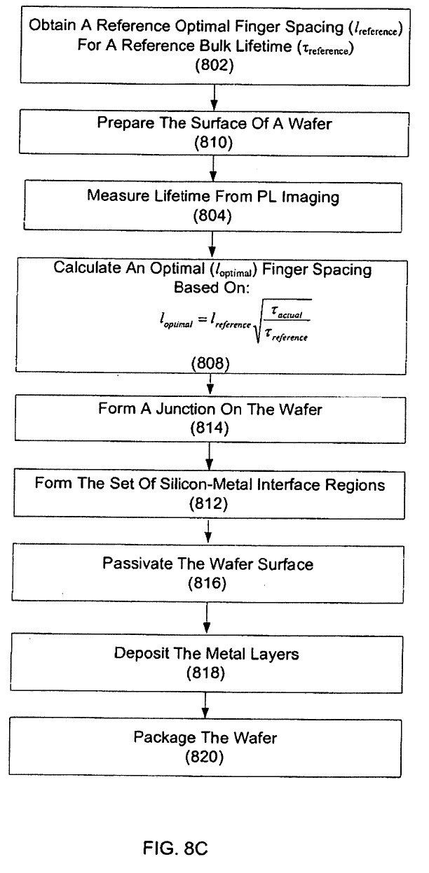

Referring now to FIGS. 8A-C, a set of simplified diagrams is shown of a (front-contact or back-contact) solar cell manufacturing process with optimized metallization and silicon-metal interface region formation, in accordance with the present invention. FIG. 8A shows the solar cell manufacturing process in which bulk resistivity is used to calculate optimal finger spacing on a computer.

Initially at 802, for a given manufacturing process, a reference optimal finger spacing is obtained for a reference bulk lifetime. A set of wafers with substantially the same bulk lifetime is selected and processed through the manufacturing line, wherein each processed wafer has a different finger spacing. The resulting efficiencies are then measured and the finger spacing (reference finger spacing) the results with the greatest efficiency (reference efficiency) is selected or derived.

Next, at 804, the resistivity for the wafer is measured using a measurement tool such as a 4-point probe.

Next at 806, using a computer, wafer bulk lifetime is calculated from the resistivity measurement determined in step 804.

At 808, an optimal finger spacing is calculated by a computer based on:

$${l}_{optimal} = {l}_{reference} \sqrt{\frac{{τ}_{actual}}{{τ}_{reference}}} \qquad [ EQUATION 5 ]$$

where T_{reference} is the reference bulk lifetime, τ_{actual} is the bulk lifetime of the current wafer, l_{reference} is the reference optimal finger spacing, and lₒₚₜᵢₘₐₗ is the optimal finger spacing of the current wafer.

Next at 810, the surface of the wafer is prepared using techniques such as exposure to alkaline and/or acid solutions, as well as plasma etching, in order to remove damage caused by the wire saw used to cut silicon ingots into wafers.

Next at 812, the set of silicon-metal interface regions is formed using a silicon-metal interface region deposition tool, such as an inkjet printer. A set of p-type silicon-metal interface regions would be formed on a p-type doped wafer region, while a set of n-type silicon-metal interface regions would be formed on an n-type doped wafer region.

In general, the silicon-metal interface region deposition tool may use a set of pre-calculated spatial patterns, wherein each optimal finger spacing would be associated with at least one pattern. In contrast, the spatial pattern may be calculated on the fly for each optimal finger spacing. For example, for silicon-metal interface regions formed with an ink printer, a deposition pattern generally must be defined in a page description language that defines the image to be printed.

Next at 814, the junction is formed on the silicon wafer typically by a tube diffusion process as previously described.

Next at 816, the surface is passivated. Typically, a layer of silicon nitride with hydrogen is deposited onto the front side of the solar cell as an antireflection coating that also serves to passivate the silicon wafer and reduce recombination losses.

At 818, the metal layers are deposited using a metal layer deposition tool, using methods such as inkjet printing, light-induced plating, laser sintering of metal powder, and metal aerosol jetting, as previously described.

Finally, at step 820, the solar cell is generally packaged. In general, sets of solar cells are electrically interconnected by a layer of the encapsulant material ethylene vinyl acetate.

FIG. 8B shows the solar cell manufacturing process in which photoluminescent imaging is used to calculate optimal finger spacing on a computer.

Initially at 802, for a given manufacturing process, a reference optimal finger spacing is obtained for a reference bulk lifetime. A set of wafers with substantially the same bulk lifetime is selected and processed through the manufacturing line, wherein each processed wafer has a different finger spacing. The resulting efficiencies are then measured and the finger spacing (reference finger spacing) the results with the greatest efficiency (reference efficiency) is selected or derived.

Next at 810, the surface of the wafer is prepared using techniques such as exposure to alkaline and/or acid solutions, as well as plasma etching, in order to remove damage caused by the wire saw used to cut silicon ingots into wafers.

Next, at 805, the bulk lifetime of the wafer is measured using photoluminescent imaging.

At 808, an optimal finger spacing is calculated by a computer based on:

$${l}_{optimal} = {l}_{reference} \sqrt{\frac{{τ}_{actual}}{{τ}_{reference}}} \qquad [ EQUATION 5 ]$$

where τ_{reference} is the reference bulk lifetime, τ_{actual} is the bulk lifetime of the current wafer, l_{reference} is the reference optimal finger spacing, and lₒₚₜᵢₘₐₗ is the optimal finger spacing of the current wafer.

Next at 812, the set of silicon-metal interface regions is formed using a silicon-metal interface region deposition tool, such as an inkjet printer, as previously described.

Next at 814, the junction is formed on the silicon wafer typically by a tube diffusion process as previously described.

Next at 816, the surface is passivated. Typically, a layer of silicon nitride with hydrogen is deposited onto the front side of the solar cell as an antireflection coating that also serves to passivate the silicon wafer and reduce recombination losses.

At step 818, the metal layers are deposited using a metal layer deposition tool, using methods such as inkjet printing, light-induced plating, laser sintering of metal powder, and metal aerosol jetting, as previously described. In addition, rear metal contacts are also deposited, commonly with a screen process.

Finally, at step 820, the solar cell is generally packaged. In general, sets of solar cells are electrically interconnected by a layer of the encapsulant material ethylene vinyl acetate.

FIG. 8C shows the solar cell manufacturing process of FIG. 8B, in which the junction is formed before forming the set of silicon-metal interface regions. That is, after 808, in which an optimal finger spacing is calculated, the junction is formed at 814 on the silicon wafer typically by a tube diffusion process as previously described. Next at 812, the set of silicon-metal interface regions are formed as previously described.

The inventions illustratively described herein may suitably be practiced in the absence of any element or elements, limitation or limitations, not specifically disclosed herein. Thus, for example, the terms “comprising,” “including,” “containing,” etc. shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the invention claimed.

Thus, it should be understood that although the present invention has been specifically disclosed by preferred embodiments and optional features, modification, improvement and variation of the inventions herein disclosed may be resorted to by those skilled in the art, and that such modifications, improvements and variations are considered to be within the scope of this invention. The materials, methods, and examples provided here are representative of preferred embodiments, are exemplary, and are not intended as limitations on the scope of the invention.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above.

All publications, patent applications, issued patents, and other documents referred to in this specification are herein incorporated by reference as if each individual publication, patent application, issued patent, or other document were specifically and individually indicated to be incorporated by reference in its entirety. Definitions that are contained in text incorporated by reference are excluded to the extent that they contradict definitions in this disclosure.

For the purposes of this disclosure and unless otherwise specified, “a” or “an” means “one or more.” All patents, applications, references and publications cited herein are incorporated by reference in their entirety to the same extent as if they were individually incorporated by reference. In addition, the word set refers to a collection of one or more items or objects.

Advantages of the invention include methods for improving performance variation of wafer-based silicon solar cells. Additional advantages include increasing the overall efficiency of a set of solar cells with minimal reconfiguration of the manufacturing process.

Having disclosed exemplary embodiments and the best mode, modifications and variations may be made to the disclosed embodiments while remaining within the subject and spirit of the invention as defined by the following claims.

What is claimed is:

1. A method for optimizing a solar cell manufacturing process, comprising:
determining a reference finger spacing value and a reference bulk lifetime for the solar cell manufacturing process;
measuring an actual bulk lifetime of a wafer with an in-line measurement tool, the wafer having a wafer surface;
calculating an optimal finger spacing value with a computer coupled to the in-line measurement tool, the optimal finger spacing value being a product of the reference finger spacing value and a square root of the actual bulk lifetime divided by the square root of the reference bulk lifetime;
forming a junction on the wafer; and
depositing a set of busbars and a set of fingers on the wafer surface with a metal deposition device, wherein a distance between a first finger and a second finger of the set of fingers is about the optimal finger spacing value.

2. The method of claim 1, further comprising passivating the wafer surface before measuring the actual bulk lifetime.

3. The method of claim 1, further comprising packaging the wafer, after depositing the set of busbars and the set of fingers on the wafer surface.

4. The method of claim 1, further comprising forming a set of silicon-metal interface regions on the wafer, wherein the set of silicon-metal interface regions is configured to be in contact with the set of busbars and the set of fingers, before depositing the set of busbars and the set of fingers on the wafer surface.

5. The method of claim 4, wherein the set of silicon-metal interface regions is formed from doped Group IV nanoparticles.

6. The method of claim 5, wherein the set of doped Group IV nanoparticles comprise one of boron and phosphorous.

7. The method of claim 1, wherein the computer is further coupled to at least one of a flash tester, a four-point probe, and a photoluminescence imaging tool.

8. The method of claim 1, further comprising exposing the wafer to at least one of an alkaline solution, an acid solution, and a plasma, before measuring the actual bulk lifetime of the wafer with the in-line measurement tool.

9. The method of claim 1, wherein the step of forming the junction on the wafer further comprises,
placing the wafer in a diffusion tube,
heating the diffusion tube to a temperature between about 800° C. and about 900° C., and
flowing nitrogen through a bubbler filled with liquid phosphorus oxychloride (POCl₃),
the bubbler further coupled to the diffusion tube.

10. The method of claim 1, wherein the wafer is monocrystalline.

11. A method for optimizing a solar cell manufacturing process, comprising:
determining a reference finger spacing value and a reference bulk lifetime for the solar cell manufacturing process;
measuring an actual bulk lifetime of a wafer with an in-line measurement tool, the wafer having a rear wafer surface;
calculating an optimal finger spacing value with a computer coupled to the in-line measurement tool, the optimal finger spacing value being a product of the reference finger spacing value and a first square root of the actual bulk lifetime divided by a second square root of the reference bulk lifetime; and
depositing a set of metal contacts on the rear wafer surface, the rear wafer surface having a set of p-type regions and a set of n-type regions, the set of metal contacts comprising a busbar and a set of fingers, wherein a first metal contact of the set of metal contacts is deposited on the set of p-type regions, and a second metal contact of the set of metal contacts is deposited on the set of n-type regions, wherein the first metal contact is interdigitated with the second metal contact, and a distance between two proximately located fingers of the first metal contact or two proximately located fingers of the second metal contact is about the optimal finger spacing value.

12. The method of claim 11, further comprising passivating the rear wafer surface before measuring the actual bulk lifetime.

13. The method of claim 11, further comprising packaging the wafer, after depositing the set of metal contacts on the rear wafer surface.

14. The method of claim 11, further comprising forming a set of p-type silicon-metal interface regions and a set of n-type silicon-metal interface regions on the wafer, wherein the set of p-type silicon-metal interface regions is configured to be in contact with the first metal contact, and the set of n-type silicon-metal interface regions is configured to be in contact with the second metal contact, before depositing the set of metal contacts on the rear wafer surface.

15. The method of claim 14, wherein the set of p-type silicon-metal interface regions and the set of n-type silicon-metal interface regions are formed from doped Group IV nanoparticles.

16. The method of claim 13, wherein the computer is further coupled to at least one of a flash tester, a four-point probe, and a photoluminescence imaging tool.

17. The method of claim 11, further comprising exposing the wafer to at least one of an alkaline solution, an acid solution, and a plasma, before measuring the actual bulk lifetime of the wafer.
